(19) United States
(12) Patent Application Publication
(10) Pub. No.: US 2009/0068818 A1
(43) Pub. Date: Mar. 12, 2009

(54) METHOD OF FORMING AN ISOLATION LAYER OF A SEMICONDUCTOR DEVICE

(75) Inventor: Wan Soo Kim, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/163,917

(22) Filed: Jun. 27, 2008

(30) Foreign Application Priority Data
Sep. 10, 2007 (KR) 2007-91548

(51) Int. Cl. H01L 21/76

(52) U.S. Cl. 438/435; 257/E21.54

(57) ABSTRACT

In a method of forming an isolation layer of a semiconductor device, a gate insulating layer, a first conductive layer, and a hard mask are formed in an active region of a semiconductor substrate and a trench is formed in an isolation region. The trench is partially gap-filled by forming a first insulating layer in the trench. The trench is fully gap-filled by forming a second insulating layer on the first insulating layer. A polishing process is performed on the first insulating layer and the second insulating layer formed over the hard mask. An etchback process is performed to lower a height of the second insulating layer in the trench. The trench is gap-filled by forming a third insulating layer over the first insulating layer and the second insulating layer, thereby forming an isolation layer in the trench. Accordingly, the occurrence of a void within the isolation layer is prevented.

### CROSS-REFERENCES TO RELATED APPLICATIONS

The present application claims priority to Korean patent application number 10-2007-0091548, filed on Sep. 10, 2007, which is incorporated by reference in its entirety.

### BACKGROUND OF THE INVENTION

The present invention relates to a method of forming an isolation layer of a semiconductor device and, more particularly, to a method of forming an isolation layer of a semiconductor device, which can form the isolation layer in an isolation region of a substrate by applying a shallow trench isolation (STI) process.

Generally, a semiconductor device formed in a silicon wafer includes isolation regions for electrically isolating semiconductor elements. In particular, with the high integration and miniaturization of semiconductor devices, active research has been done on a reduction in the size of each individual element and the isolation region. The formation of the isolation region is an initial process step and determines the size of an active region and process margin of post-process steps.

A field oxide layer is formed in the isolation region by a typical method, such as local oxidation of silicon (LOCOS) or profiled grove isolation (PGI), so that the active region is defined. In the LOCOS method, a nitride layer, that is, an oxidization-prevention mask to define the active region, is formed on a semiconductor substrate and then patterned to expose some of the semiconductor substrate. The exposed semiconductor substrate is oxidized to form the field oxide layer that is used as the isolation region. The LOCOS method is advantageous in that the process is simple, and wide and narrow portions can be separated at the same time. However, the LOCOS method is disadvantageous in that a bird's beak occurs due to lateral oxidization, which widens the width of the isolation region, and the effective areas of source/drain regions can be reduced. The LOCOS method is also disadvantageous in that crystalline defects are generated in the silicon substrate because stress according to a difference in the coefficient of thermal expansion is concentrated on the corners of the oxide layer when the field oxide layer is formed and, therefore, the leakage current is increased. Furthermore, with the high integration of semiconductor devices, the design rule is decreased and therefore the size of semiconductor elements and isolation layers for isolating the semiconductor elements is decreased on the same scale. Accordingly, typical isolation methods, such as LOCOS, have reached their limit.

A STI method for solving the above problems is described below. First, a nitride layer having an etch selectivity different from that of a semiconductor substrate is formed on the semiconductor substrate. In order to use the nitride layer as a hard mask pattern, the nitride layer is patterned to form a nitride layer pattern. Trenches are formed by etching the semiconductor substrate to a specific depth using an etch process employing the nitride layer pattern. The trenches are gap-filled with an oxide layer, such as a high-density plasma (HDP) oxide layer. Since it is difficult to gap-fill all of the trenches at once, the gap-fill process is performed repeatedly to fully gap-fill the trenches. Next, isolation layers are formed to gap-fill the trenches by performing chemical mechanical polishing (CMP).

However, there is a difference in the surface of the oxide layer formed in the trenches located at middle and peripheral portions of a wafer due to the characteristics of manufacturing equipment. In other words, the oxide layer formed in the trench located at the central portion of the wafer has a relatively flat surface, but the oxide layer formed in the trench located in the peripheral portion of the wafer has an inclined surface since a deposition angle is not vertical. In particular, if the surface of the oxide layer formed in the trench located in the peripheral portion of the wafer is inclined, deposition failure is generated when subsequently gap-filling the trench with the oxide layer, so that a void may occur within the isolation layer. This void remains in subsequent processes. Consequently, the isolation layer can be etched excessively in a subsequent effective field height (EFH) control process.

### BRIEF SUMMARY OF THE INVENTION

The present invention is directed to prevent the occurrence of a void within an isolation layer such that, when the isolation layer is formed using a STI process, a trench is gap-filled with a HDP oxide layer, a spin on dielectric (SOD) with an excellent gap-fill capability is formed on an inclined surface of the HDP oxide layer to make the surface flat, and the gap-filling of the trench is completed.

According to a method of forming an isolation layer of a semiconductor device in accordance with an aspect of the present invention, a semiconductor substrate over which a gate insulating layer, a first conductive layer, and a hard mask are formed in an active region and a trench is formed in an isolation region is provided. The trench is partially gap-filled by forming a first insulating layer at a bottom of the trench. The trench is fully gap-filled by forming a second insulating layer, having fluidity, on the first insulating layer. A polishing process is performed on the first insulating layer and the second insulating layer formed over the hard mask. An etchback process is performed to lower a height of the second insulating layer. The trench is gap-filled by forming a third insulating layer over the first insulating layer and the second insulating layer, thereby forming an isolation layer in the trench.

The second insulating layer may include a spin on dielectric (SOD) oxide layer. The second insulating layer may include one of a poly silazane (PSZ) oxide layer, a hydrogen silsesquioxane (HSQ) oxide layer and a T12 oxide layer. The first insulating layer or the third insulating layer may include a high-density plasma (HDP) oxide layer. The polishing process may remove the first insulating layer and the second insulating layer at the same ratio. The first insulating layer may be formed to a thickness of 400 to 800 angstroms. The second insulating layer may be formed to a thickness of 1000 to 4000 angstroms. When the etchback process is performed, the second insulating layer may be removed to a thickness of 100 to 400 angstroms. The third insulating layer may be formed to a thickness of 1500 to 3000 angstroms. A process of lowering a height of the isolation layer may be further performed after the isolation layer is formed. The process of lowering the height of the isolation layer may be performed such that the HDP oxide layer and the SOD oxide layer have an etch selectivity of 1:1. The process of lowering the height of the isolation layer may be performed using a dry etch process. The process of lowering the height of the isolation layer may be performed using one of C₄F₆ gas, C₄F₈ gas, and CH₂F₂ gas as an etch gas. The process of lowering the height of the isolation layer may further include using CO as the etch gas. The hard mask may be formed of a nitride layer. The first insulating layer may have an inclined surface within the trench, when the trench is formed in a peripheral portion of the semiconductor substrate.

### BRIEF DESCRIPTION OF THE DRAWINGS

FIGS. 1A to 1I are cross-sectional views illustrating a method of forming an isolation layer of a semiconductor device in accordance with the present invention.

### DESCRIPTION OF SPECIFIC EMBODIMENT

A specific embodiment according to the present invention will be described with reference to the accompanying drawings. However, the present invention is not limited to the disclosed embodiment, but may be implemented in various ways. The embodiment is provided to complete the disclosure of the present invention and to allow those having ordinary skill in the art to understand the present invention. The present invention is defined by the scope of the claims.

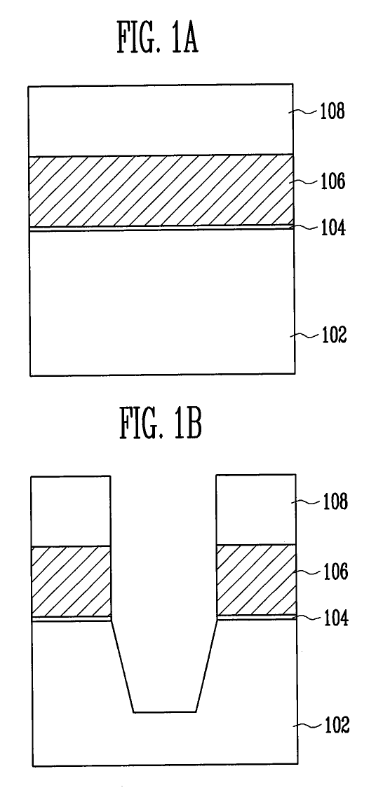

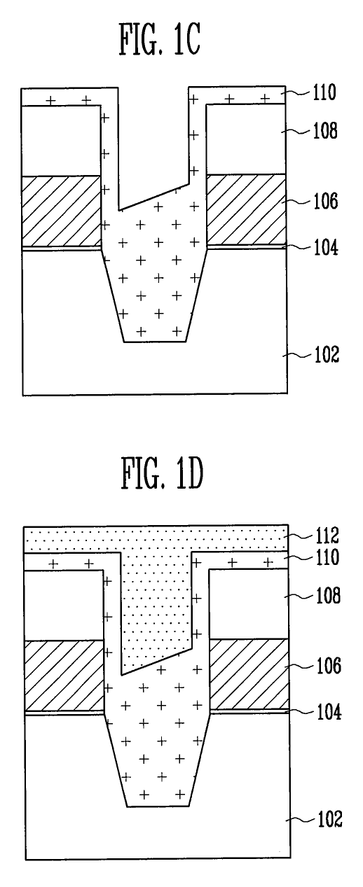

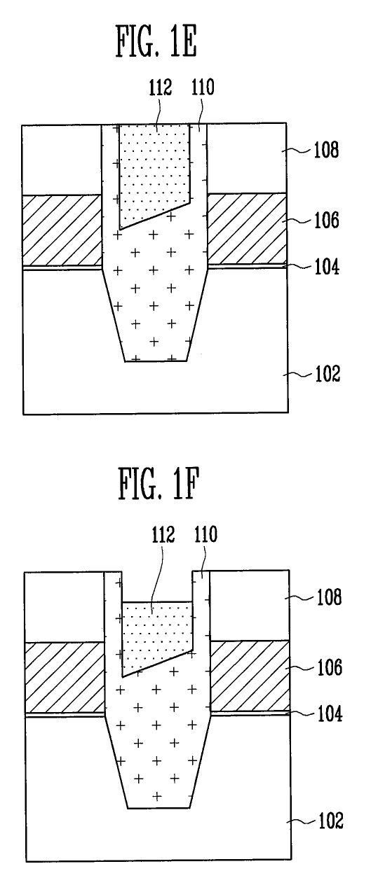

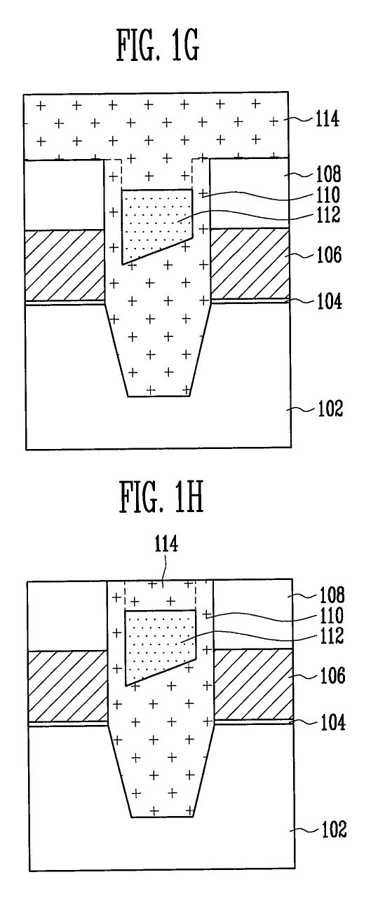

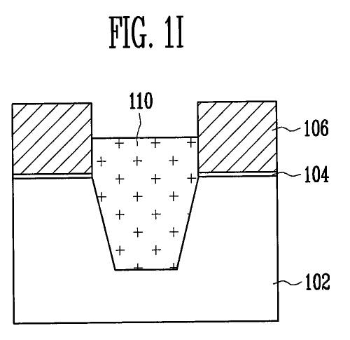

FIGS. 1A to 1I are cross-sectional views illustrating a method of forming an isolation layer of a semiconductor device in accordance with the present invention.

Referring to FIG. 1A, a screen oxide layer (not shown) is formed on a semiconductor substrate 102, including an active region (not shown) in which a NAND flash memory device is formed and an isolation region (not shown). A well ion implantation process or a threshold voltage ion implantation process is performed on the semiconductor substrate 102. The well ion implantation process is performed to form a well region in the semiconductor substrate 102. The threshold voltage ion implantation process is performed to control the threshold voltage of a semiconductor element such as a transistor. The screen oxide layer (not shown) functions to prevent damage to the surface of the semiconductor substrate 102 when the well ion implantation process or the threshold voltage ion implantation process is performed. Thus, the well region (not shown) is formed in the semiconductor substrate 102. The well region may have a triple structure.

After the screen oxide layer (not shown) is removed, a tunnel insulating layer 104 is formed on the semiconductor substrate 102. The tunnel insulating layer 104 may be formed of an oxide layer. The tunnel insulating layer allows electrons to pass from a channel junction, formed below the tunnel insulating layer, to a floating gate, formed on the tunnel insulating layer, through Fowler/Nordheim (F/N) tunneling. A conductive layer 106 for the floating gate is formed on the tunnel insulating layer 104. The conductive layer 106 may trap electric charges, transferred from the channel junction formed below the tunnel insulating layer 104, or discharge the electric charges toward the channel junction. The conductive layer 106 may be formed from polysilicon. A hard mask 108 may be formed over the conductive layer 106. The hard mask 108 may be formed of a nitride layer so that it can function as an etch-stop layer in a subsequent polishing process such as CMP. Meanwhile, a buffer layer (not shown), made of an oxide layer, may be further formed between the hard mask 108 and the conductive layer 106.

Referring to FIG. 1B, patterns are formed by etching the hard mask 108, the conductive layer 106, and the gate insulating layer 104 of a region corresponding to the isolation region of the semiconductor substrate 102. The semiconductor substrate 102 is then partially etched to form a trench 114. The trench 114 may have a tapered width extending downwardly. To compensate for sidewalls of the trench that may be damaged during the etch process, an oxidization process may be performed on the trench sidewalls to form a wall oxide layer (not shown).

Referring to FIG. 1C, a first insulating layer 110 is formed over the semiconductor substrate 102 including the trench. The first insulating layer 110 may be formed of a HDP oxide layer with an excellent film quality. The first insulating layer 110 may be formed to a thickness of 400 to 800 angstroms in order to gap-fill only some of the trench 114, so that a surface of the first insulating layer 110 in the trench corresponds to a middle portion of the conductive layer 106. The surface of the first insulating layer 110 within the trench, which is positioned in a peripheral portion of the semiconductor substrate 102, may be inclined, as shown in the drawings.

Referring to FIG. 1D, a second insulating layer 112 is formed on the first insulating layer 110. It may be preferred that the second insulating layer 112 be formed from a SOD oxide layer with an excellent gap-fill characteristic, such as a poly silazane (PSZ) oxide layer, a hydrogen silsesquioxane (HSQ) oxide layer or an T12 oxide layer, since the second insulating layer 112 has a fluid characteristic. The second insulating layer 112 may be formed to a thickness enough to fully cover the first insulating layer 110 formed in the trench, for example, 1000 to 4000 angstroms. Accordingly, the empty space above the first insulating layer 110 within the trench can be easily gap-filled with the second insulating layer 112.

Referring to FIG. 1E, the second insulating layer 112 and the first insulating layer 110 formed over the hard mask 108 are removed by a polishing process, such as a chemical and/or physical polishing method, using the hard mask 108 as an etch-stop layer. In the polishing process, a ratio in which the first insulating layer 110 and the second insulating layer 112 are removed may be identical, i.e., 1:1. Accordingly, the first insulating layer 110 and the second insulating layer 112 remain only within the trench, and a top surface of the second insulating layer 112 is exposed.

Referring to FIG. 1F, an etchback process is performed on the exposed second insulating layer 112. The second insulating layer 112 is etched approximately four times more than the first insulating layer 110 during a wet etch. Thus, the etchback process is performed using an etchant so that the second insulating layer 112 is more etched than the first insulating layer 110. An etched thickness of the second insulating layer 112 can range from 100 to 400 angstroms so that variation is not generated due to the etchant in a subsequent process of removing the hard mask 108. Thus, a space is formed above the second insulating layer 12 between upper portions of the first insulating layer 110.

Referring to FIG. 1G, a third insulating layer 114 is formed on the hard mask 108, including the first insulating layer 110 and the second insulating layer 112. The third insulating layer 114 may be formed using the same HDP oxide layer as the first insulating layer 110. Further, the third insulating layer 114 may be formed to a thickness of 1500 to 3000 angstroms so that the space formed in the trench is fully gap-filled.

Referring to FIG. 1H, the third insulating layer 114 formed on the hard mask 108 is removed by performing a polishing process, such as a chemical and/or physical polishing method, using the hard mask 108 as an etch-stop layer. Consequently, an isolation layer, including the first insulating layer 110, the second insulating layer 112, and the third insulating layer 114, is formed in the trench.

Referring to FIG. 1I, in order to increase the coupling ratio, an etch process is performed on the third insulating layer 114, the second insulating layer 112, and the first insulating layer 110 to lower the height of the isolation layer in the trench The etch process can be performed by a dry etch process using C₄F₆ gas, C₄F₈ gas, or CH₂F₂ gas as an etch gas such that the etch selectivity of the HDP oxide layer and the SOD oxide layer is 1:1. By increasing the selectivity by mixing CO in the etch gas, the hard mask 108 is not removed. In this case, the height of the isolation layer in the trench is lowered until the second insulating layer 112 is fully removed. The hard mask (refer to 108 of FIG. 1H) is then removed.

According to the method of forming the isolation layer of the semiconductor device in accordance with the present invention, after the trench is gap-filled with the HDP oxide layer, the SOD layer having an excellent gap-fill capability is formed on the inclined surface of the HDP oxide layer in the trench to make the surface flat. The trench is thereby fully gap-filled, so that a void can be prevented from occurring in the isolation layer. Accordingly, an isolation layer having an excellent film quality can be formed without generating a void or a seam.

The embodiment disclosed herein has been proposed to allow a person skilled in the art to easily implement the present invention, and the person skilled in the part may implement the present invention in various ways. Therefore, the scope of the present invention is not limited by or to the embodiment as described above, and should be construed to be defined only by the appended claims and their equivalents.

1. A method of forming an isolation layer of a semiconductor device, the method comprising:
forming a gate insulating layer, a first conductive layer, and a hard mask in an active region of a semiconductor substrate;
forming a trench in an isolation region of the semiconductor substrate;
gap-filling a portion of the trench by forming a first insulating layer at a bottom of the trench, wherein the first insulating layer is formed with an inclined top surface at a central region of the trench;
gap-filling a remaining portion of the trench by forming a second insulating layer over the first insulating layer, wherein the second insulating layer has a fluid characteristic;
polishing the first insulating layer and the second insulating layer formed over the hard mask;
etching the second insulating layer to lower a height of the second insulating layer in the trench; and
gap-filling the trench by forming a third insulating layer over the first insulating layer and the second insulating layer, thereby forming an isolation layer in the trench.

2. The method of claim 1, wherein the second insulating layer comprises a spin on dielectric (SOD) oxide layer.

3. The method of claim 1, wherein the second insulating layer comprises one of a poly silazane (PSZ) oxide layer, a hydrogen silsesquioxane (HSQ) oxide layer and an T12 oxide layer

4. The method of claim 1, wherein the first insulating layer and the third insulating layer comprise a high-density plasma (HDP) oxide layer.

5. The method of claim 1, wherein polishing the first insulating layer and the second insulating layer removes the first insulating layer and the second insulating layer at the same ratio.

6. The method of claim 1, wherein the first insulating layer is formed to a thickness of 400 to 800 angstroms.

7. The method of claim 1, wherein the second insulating layer is formed to a thickness of 1000 to 4000 angstroms.

8. The method of claim 1, wherein etching the second insulating layer comprises removing the second insulating layer to a thickness of 100 to 400 angstroms.

9. The method of claim 1, wherein the third insulating layer is formed to a thickness of 1500 to 3000 angstroms.

10. The method of claim 1, further comprising lowering a height of the isolation layer in the trench.

11. The method of claim 10, wherein lowering the height of the isolation layer is performed such that the first insulating layer and the second insulating layer have an etch selectivity of 1:1.

12. The method of claim 10, wherein lowering the height of the isolation layer is performed using a dry etch process.

13. The method of claim 10, wherein lowering the height of the isolation layer is performed using one of C₄F₆ gas, C₄F₈ gas, and CH₂F₂ gas as an etch gas.

14. The method of claim 13, wherein lowering the height of the isolation layer further comprises using CO as the etch gas.

15. The method of claim 1, wherein the hard mask comprises a nitride layer.

16. The method of claim 1, wherein the trench is formed in a peripheral portion of the semiconductor substrate.
